(19) United States
(12) Patent Application Publication
(10) Pub. No.: US 2025/0048808 A1
(43) Pub. Date: Feb. 6, 2025

(54) LIGHT EMITTING DIODE PACKAGE STRUCTURE AND LIGHT EMITTING DIODE DISPLAY APPARATUS

(71) Applicant: EXCELLENCE OPTO., INC., Miaoli County (TW)

(72) Inventors: KUO-HSIN HUANG, Miaoli County (TW); TZENG-GUANG TSAI, Miaoli County (TW); CHANG HUNG PAN, Miaoli County (TW); CHANG-CHING HUANG, Miaoli County (TW)

(21) Appl. No.: 18/784,985

(22) Filed: Jul. 26, 2024

(30) Foreign Application Priority Data
Aug. 4, 2023 (TW) 112129384

(51) Int. Cl. H01L 33/58; H01L 25/075

(52) U.S. Cl. CPC H01L 33/58; H01L 25/0753

(57) ABSTRACT

An LED package structure includes three LED dies and a black sealant layer. Each of the LED dies is provided with a bottom surface, a top surface, and a peripheral wall. The bottom surface and the top surface are opposite to each other, and the peripheral wall is connected to the top surface and the bottom surface. The black sealant layer is coated among the three LED dies and coats the peripheral wall of each of the LED dies. The black sealant layer is provided with a joint surface. The joint surface is coplanar with the bottom surface of each of the LED dies. The black sealant layer does not cover the top surface of each of the LED dies. Also provided is an LED display apparatus which has a better visual taste.

### FIELD OF THE INVENTION

The present invention relates to a package structure and a display apparatus, and particularly relates to a light emitting diode (LED) package structure and an LED display apparatus.

### BACKGROUND OF THE INVENTION

LED display apparatuses gain the popularity gradually due to their display quality with high color saturation, fast speed of response, and high contrast. Most LED display apparatuses use micron-order micro LEDs as sub-pixels in the display apparatuses. The micro LEDs can be subjected to addressing control and can be driven by a single point to emit light. The micro LEDs also have the advantages of high brightness, low power consumption, high resolution and color saturation, and the like. However, with increase of the quantity of the micro LEDs used, circuits on a circuit board become tedious gradually, and solder paste for adhering the micro LEDs to the circuit board is gradually increased. As the circuits and solder paste on the circuit board are likely to reflect incident light to affect contrast of the LED display apparatuses, a visual defect is caused.

### SUMMARY OF THE INVENTION

The present invention provides an LED package structure and an LED display apparatus. The LED display apparatus has a better visual taste.

The LED package structure provided by the present invention includes a first LED die, a second LED die, a third LED die, and a black sealant layer. The first LED die is provided with a first bottom surface, a first top surface, and a first peripheral wall, wherein the first bottom surface and the first top surface are opposite to each other, and the first peripheral wall is connected to the first bottom surface and the first top surface opposite to each other. The second LED die is provided with a second bottom surface, a second top surface, and a second peripheral wall, wherein the second bottom surface and the second top surface are opposite to each other, and the second peripheral wall is connected to the second bottom surface and the second top surface opposite to each other. The third LED die is provided with a third bottom surface, a third top surface, and a third peripheral wall, wherein the third bottom surface and the third top surface are opposite to each other, and the third peripheral wall is connected to the third bottom surface and the third top surface opposite to each other. The black sealant layer is coated among the first LED die, the second LED die, and the third LED die and coats the first peripheral wall, the second peripheral wall, and the third peripheral wall, wherein the black sealant layer is provided with a joint surface, the joint surface is coplanar with the first bottom surface, the second bottom surface, and the third bottom surface, and the black sealant layer does not cover the first top surface, the second top surface, and the third top surface.

The LED display apparatus provided by the present invention includes a circuit board, a plurality of LED package structures, and a transparent adhesive layer. The circuit board is provided with a plurality of circuit endpoint groups, wherein each of the circuit endpoint groups includes at least three endpoints. The LED package structures are arranged on the circuit board and are electrically connected to the circuit endpoint groups, receptively, wherein the black sealant layer of each of the LED package structures is not connected to the black sealant layer of another adjacent LED package structure, and there is a gap between the black sealant layers. The transparent adhesive layer is arranged on the circuit board, covers the LED package structures, and fills the gap.

In an embodiment of the present invention, the first LED die, the second LED die, and the third LED die are respectively a blue LED die, a green LED die, and a red LED die.

In an embodiment of the present invention, the LED package structure further includes a lens structural layer, arranged on the black sealant layer and covering the first LED die, the second LED die, and the third LED die.

In an embodiment of the present invention, the lens structural layer includes a resin material layer and a plurality of white diffusive particles, and the white diffusive particles are distributed in the resin material layer.

In an embodiment of the present invention, the lens structural layer includes a resin material layer, white acrylic spheres, and a black film layer, the white acrylic spheres are distributed in the resin material layer, and the black film layer is arranged on a side of the resin material layer away from the black sealant layer.

In an embodiment of the present invention, the lens structural layer includes a resin material layer and a plurality of black powder particles, and the black powder particles are distributed in the resin material layer.

In an embodiment of the present invention, a plurality of microstructures are formed on a side of the lens structural layer away from the black sealant layer.

In an embodiment of the present invention, the LED package structure further includes a package substrate, an upper surface of the package substrate is provided with a plurality of welding pads, the joint surface of the black sealant layer is connected to the upper surface, and the first LED die, the second LED die, and the third LED die are electrically connected to the welding pads, respectively.

In an embodiment of the present invention, the LED package structure further includes a redistribution layer including a plurality of fan-out conductive structures, the joint surface of the black sealant layer is connected to the redistribution layer, and the first LED die, the second LED die, and the third LED die are electrically connected to the fan-out conductive structures, respectively.

In an embodiment of the present invention, surface microstructures are formed on a side of the transparent adhesive layer away from the circuit board.

In an embodiment of the present invention, ultraviolet absorption particles are distributed in the transparent adhesive layer.

In an embodiment of the present invention, the LED package structures are adhered to the circuit board via a metal conductive adhesive.

In an embodiment of the present invention, the LED display apparatus further includes a plurality of spacers, arranged on the circuit board, and located among the LED package structures, and the transparent adhesive layer further coats the spacers.

In an embodiment of the present invention, a shape of each of the spacers is of a single column structure.

In an embodiment of the present invention, the shape of each of the spacers is of a perforated array arrangement structure.

In an embodiment of the present invention, the transmittance and refractive index of the spacers correspond to the transmittance and refractive index of the transparent adhesive layer.

In the present invention, every three LED dies in a group are assembled together by utilizing the black sealant layer, and the black sealant layer does not cover the top surfaces of the LED dies. When the LED package structures are jointed to the circuit board, a reflection mechanism of conventional solder paste or a metal conductive adhesive and a circuit layer on a circuit board can be shielded synchronously, so as to prevent affecting contrast of the LED display apparatus, so the LED display apparatus has a better visual taste. In addition, by selecting and arranging the lens structural layer of the LED package structure, the purposes of improving the light pattern of the LED dies and reducing the color shift can further be achieved.

### BRIEF DESCRIPTION OF THE DRAWINGS

The present invention will become more readily apparent to those ordinarily skilled in the art after reviewing the following detailed description and accompanying drawings, in which:

FIG. 1A and FIG. 1B show cross-sectional schematic diagrams of LED package structures according to two first embodiments of the present invention;

FIG. 2A and FIG. 2B show cross-sectional schematic diagrams of LED package structures according to two second embodiments of the present invention;

FIG. 3A and FIG. 3B show cross-sectional schematic diagrams of LED package structures according to two third embodiments of the present invention;

FIG. 4A and FIG. 4B show cross-sectional schematic diagrams of LED display apparatuses according to two first embodiments of the present invention;

FIG. 5A and FIG. 5B show cross-sectional schematic diagrams of LED display apparatuses according to two second embodiments of the present invention;

FIG. 6A and FIG. 6B show cross-sectional schematic diagrams of LED display apparatuses according to two third embodiments of the present invention;

FIG. 7A and FIG. 7B show cross-sectional schematic diagrams of LED display apparatuses according to two fourth embodiments of the present invention;

FIG. 8A, FIG. 8B, and FIG. 8C show top view schematic diagrams of spacers according to an embodiment in different patterns; and

FIG. 9A, FIG. 9B, and FIG. 9C show top view schematic diagrams of spacers according to another embodiment in different patterns.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

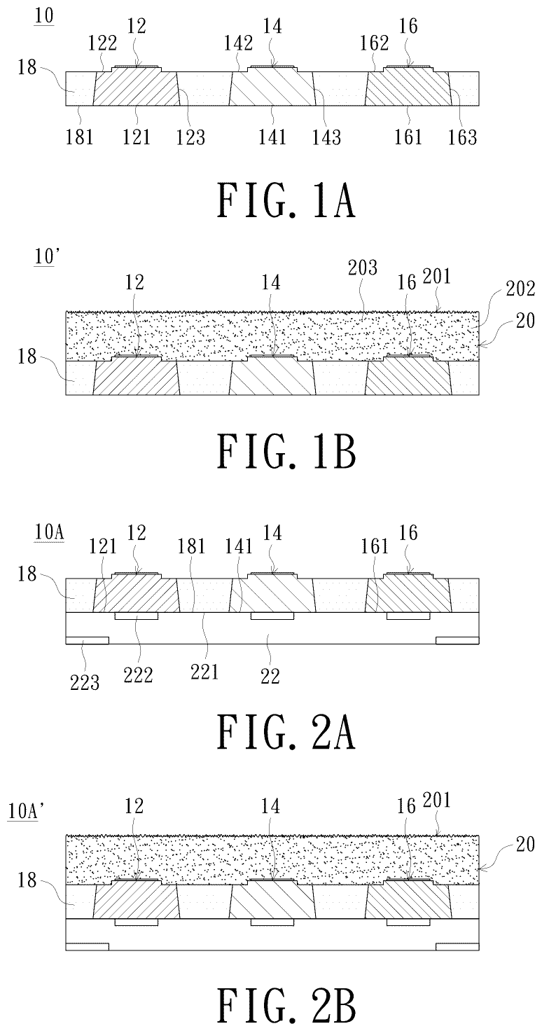

FIG. 1A and FIG. 1B show cross-sectional schematic diagrams of LED package structures according to two first embodiments of the present invention. As shown in FIG. 1A, the LED package structure 10 includes a first LED die 12, a second LED die 14, a third LED die 16, and a black sealant layer 18. The first LED die 12 is provided with a first bottom surface 121, a first top surface 122, and a first peripheral wall 123, wherein the first bottom surface 121 and the first top surface 122 are opposite to each other, and the first peripheral wall 123 is connected to the first bottom surface 121 and the first top surface 122 opposite to each other. The second LED die 14 is provided with a second bottom surface 141, a second top surface 142, and a second peripheral wall 143, wherein the second bottom surface 141 and the second top surface 142 are opposite to each other, and the second peripheral wall 143 is connected to the second bottom surface 141 and the second top surface 142 opposite to each other. The third LED die 16 is provided with a third bottom surface 161, a third top surface 162, and a third peripheral wall 163, wherein the third bottom surface 161 and the third top surface 162 are opposite to each other, and the third peripheral wall 163 is connected to the third bottom surface 161 and the third top surface 162 opposite to each other. In an embodiment, the first LED die 12, the second LED die 14, and the third LED die 16 are, for example, respectively a blue LED die, a green LED die, and a red LED die, and the patterns of the LED dies can be selected from Mini-LEDs, micro-LEDs, and the like, wherein, for example, die pins (not shown in the drawings) are exposed on the first bottom surface 121, the second bottom surface 141, and the third bottom surface 161. Optionally, the LED die can be, for example, of a flip chip structure or a vertical chip structure. When the LED die is of the flip chip structure, a p-electrode and an n-electrode of the LED die are both, for example, located at the bottom side of the LED die; and when the LED die is of the vertical chip structure, the p-electrode and the n-electrode are, for example, located at the top side and the bottom side of the LED die.

To continue with the above description, the black sealant layer 18 is coated among the first LED die 12, the second LED die 14, and the third LED die 16, and coats the first peripheral wall 123, the second peripheral wall 143, and the third peripheral wall 163, wherein the black sealant layer 18 is provided with a joint surface 181, the joint surface 181 is coplanar with the first bottom surface 121, the second bottom surface 141, and the third bottom surface 161, and the black sealant layer 18 does not cover the first top surface 122, the second top surface 142, and the third top surface 162. In an embodiment, the black sealant layer 18, for example, fully coats or partially coats the first peripheral wall 123, the second peripheral wall 143, and the third peripheral wall 163.

As shown in FIG. 1B, an LED package structure 10′ in another first embodiment of the present invention further includes a lens structural layer 20, arranged on the black sealant layer 18 and covering the first LED die 12, the second LED die 14, and the third LED die 16. In an embodiment of the present invention, a plurality of microstructures 201 are formed on a side of the lens structural layer 20 away from the black sealant layer 18, i.e., the surface of the lens structural layer 20 is coarsened to reduce occurrence of reflection.

In an embodiment, the lens structural layer 20 includes, for example, a resin material layer 202 and a plurality of white diffusive particles 203, and the white diffusive particles 203 are distributed in the resin material layer 202. Therefore, the lens structural layer 20 is arranged on the black sealant layer 18 to improve the light patterns of the first LED die 12, the second LED die 14, and the third LED die 16 and reduce the color shift.

In an embodiment not shown, the above white diffusive particles 203 can be replaced by white acrylic spheres, and the white acrylic spheres are distributed in the resin material layer 202. The lens structural layer 20 can further include a black film layer, arranged on the resin material layer 202, i.e., the resin material layer 202 is located between the black film layer and the black sealant layer 18, wherein the black film layer is, for example, a black coating, so that rays emitted by the first LED die 12, the second LED die 14, and the third LED die 16 are partially refracted and absorbed.

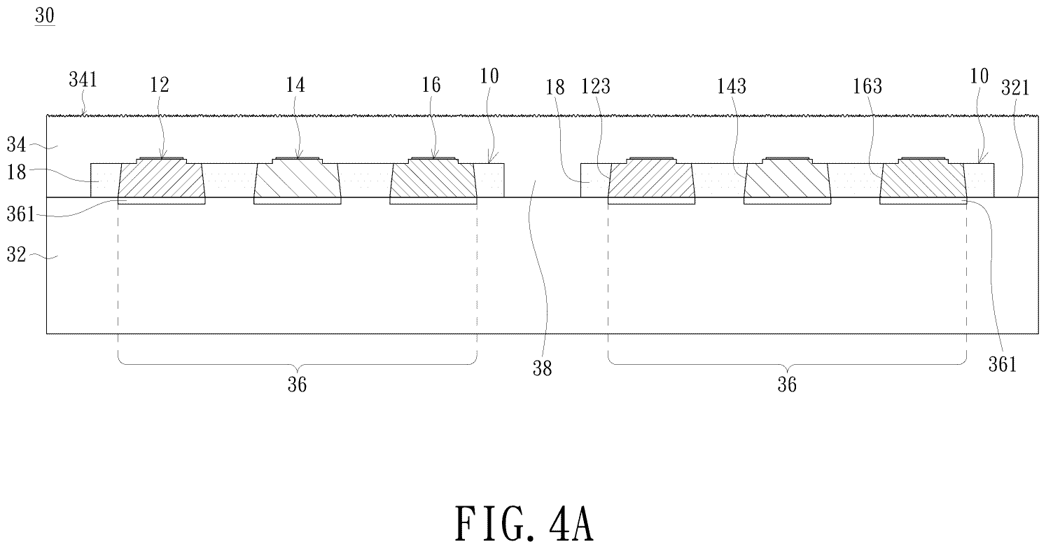

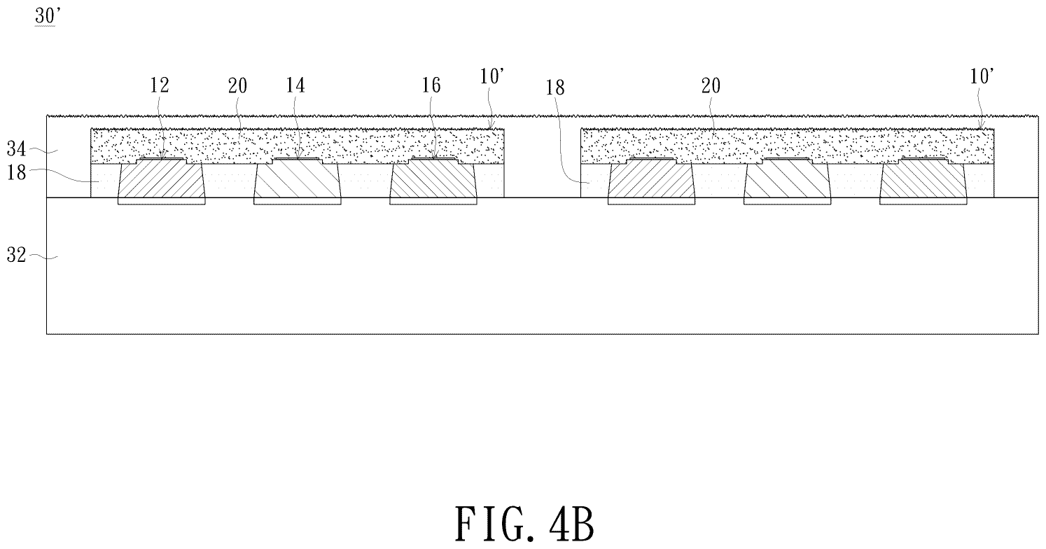

In an embodiment, the above white diffusive particles 203 can be replaced by black powder particles, and the black powder particles are distributed in the resin material layer 202. By arranging the lens structural layer 20 with the black powder particles on the black sealant layer 18, the whole LED package structure 10′ can be presented in a blackened state, so that when the LED package structure 10′ is subsequently arranged on the circuit board 32 (marked in FIG. 4B described below) to form the LED display apparatus, the metal conductive adhesive or the solder paste, which connects the LED package structure 10′ and the circuit board 32, can be prevented from being exposed and seen and affecting the visual taste of the whole LED display apparatus.

FIG. 2A and FIG. 2B show cross-sectional schematic diagrams of LED package structures according to two second embodiments of the present invention. As shown in FIG. 2A, the difference between the LED package structure 10A in one of the second embodiments and the LED package structure 10 in one of the first embodiments mainly lies in that the LED package structure 10A further includes a package substrate 22, an upper surface 221 of the package substrate 22 is provided with a plurality of welding pads 222, the welding pads 222 are, for example, deposited on the upper surface 221 of the package substrate 22, the joint surface 181 of the black sealant layer 18 is connected to the upper surface 221, and the first LED die 12, the second LED die 14, and the third LED die 16 are electrically connected to the welding pads 222, respectively. In an embodiment, for example, the die pins (not shown in the drawings) exposed via the first bottom surface 121, the second bottom surface 141, and the third bottom surface 161 contact with the welding pads 222 and are electrically connected to the same.

In an embodiment, the material of the package substrate 22 is, for example, a printed circuit board (PCB), a bismaleimide-triazine (BT) resin support board, an epoxy molding compound (EMC) substrate or a silicone molding compound (SMC) substrate. Further, in an embodiment, a conductive circuit structure 223 is exposed to a side of the package substrate 22 away from the black sealant layer 18.

To continue with the above description, as shown in FIG. 2B, an LED package structure 10A′ in another second embodiment of the present invention further includes a lens structural layer 20, arranged on the black sealant layer 18 and covering the first LED die 12, the second LED die 14, and the third LED die 16. In an embodiment of the present invention, a plurality of microstructures 201 are formed on a side of the lens structural layer 20 away from the black sealant layer 18, i.e., the surface of the lens structural layer 20 is coarsened to reduce occurrence of reflection. Further, the structure and compositions of the lens structural layer 20 have been revealed in the LED package structure 10′ in the first embodiment, which are not repeatedly described herein.

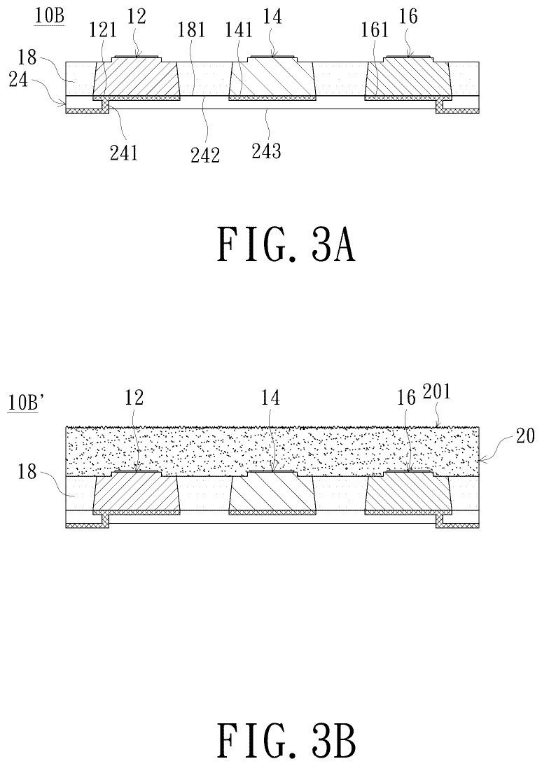

FIG. 3A and FIG. 3B show cross-sectional schematic diagrams of LED package structures according to two third embodiments of the present invention. As shown in FIG. 3A, the difference between the LED package structure 10B in one of the third embodiments and the LED package structure 10 in one of the first embodiments mainly lies in that the LED package structure 10B further includes a redistribution layer 24 including a plurality of fan-out conductive structures 241, a part of the fan-out conductive structures 241 are exposed to the top side 242 and the bottom side 243 of the redistribution layer 24; the joint surface 181 of the black sealant layer 18 contacts with and is connected to the top side 242 of the redistribution layer 24, and the first LED die 12, the second LED die 14, and the third LED die 16 are electrically connected to the part of fan-out conductive structures 241 exposed to the top side 242, respectively. In an embodiment, for example, the die pins (not shown in the drawings) exposed via the first bottom surface 121, the second bottom surface 141, and the third bottom surface 161 contact with the part of exposed fan-out conductive structures 241 and are electrically connected to the same.

To continue with the above description, as shown in FIG. 3B, an LED package structure 10B′ in another third embodiment of the present invention further includes a lens structural layer 20, arranged on the black sealant layer 18 and covering the first LED die 12, the second LED die 14, and the third LED die 16. In an embodiment of the present invention, a plurality of microstructures 201 are formed on a side of the lens structural layer 20 away from the black sealant layer 18, i.e., the surface of the lens structural layer 20 is coarsened to reduce occurrence of reflection. Further, the structure and compositions of the lens structural layer 20 have been revealed in the LED package structure 10′ in the first embodiment, which are not repeatedly described herein.

FIG. 4A and FIG. 4B show cross-sectional schematic diagrams of LED display apparatuses according to two first embodiments of the present invention. As shown in FIG. 4A, the LED package structure 30 includes a circuit board 32, a plurality of LED package structures 10, and a transparent adhesive layer 34. A surface 321 of the circuit board 32 is provided with a plurality of circuit endpoint groups 36, wherein each of the circuit endpoint groups 36 includes, for example, at least three endpoints 361. In an embodiment, the endpoints 361 are, for example, the welding pads, and the welding pads are, for example, deposited on the surface 321 of the circuit board 32. The plurality of LED package structures 10 are arranged on the surface 321 of the circuit board 32, and are electrically connected to the circuit endpoint groups 36, respectively, i.e., each of the LED package structures 10 is correspondingly and electrically connected to one of the circuit endpoint groups 36. Description is made in FIG. 4A taking two circuit endpoint groups 36 and two groups of LED package structures 10 as examples, but is not limited hereto.

To continue the above description, each of the LED package structures 10 includes the first LED die 12, the second LED die 14, the third LED die 16, and the black sealant layer 18. The black sealant layer 18 is coated among the first LED die 12, the second LED die 14, and the third LED die 16 and coats the first peripheral wall 123 of the first LED die 12, the second peripheral wall 143 of the second LED die 14, and the third peripheral wall 163 of the third LED die 16, and further, the black sealant layer 18 does not cover the first LED die 12, the second LED die 14, and the third LED die 16. The position distribution of the endpoints 361 included in each of the circuit endpoint groups 36 on the circuit board 32, for example, corresponds to that of the first LED die 12, the second LED die 14, and the third LED die 16 on the single LED package structure 10. When each of the LED package structures 10, corresponding to one of the circuit endpoint groups 36, is arranged on the circuit board 32, the first LED die 12, the second LED die 14, and the third LED die 16 respectively contact with the endpoints 361 of each of the circuit endpoint groups 36 and are electrically connected to the same.

When the plurality of LED package structures 10 are, for example, adhered to the circuit board 32 via the metal conductive adhesive (not shown in the drawings), the black sealant layer 18 of each of the LED package structures 10 is not connected to the black sealant layer 18 of another adjacent LED package structure 10, and there is a gap 38 between the black sealant layers 18. Further, the transparent adhesive layer 34 is arranged on the circuit board 32, covers the LED package structures 10, and fills the gap 38. The material of the transparent adhesive layer 34 is, for example, a transparent resin.

As described above, in the LED display apparatus 30 in an embodiment of the present invention, the LED package structure 10 may be protected and the optical color rendering may be optimized via molding of the transparent adhesive layer 34. In an embodiment, ultraviolet absorption particles (not shown in the drawings) may be added into the transparent adhesive layer 34 to resist the characteristic that ultraviolet rays deteriorate the transparent adhesive layer 34, so as to alleviate the probability of occurrence of yellowing. In an embodiment, a plurality of surface microstructures 341 may further be formed on a side of the transparent adhesive layer 34 away from the circuit board 32. A manufacturing method for the surface microstructures 341 includes, for example, transfer printing, abrasive blasting, reducing, cutting, or pasting, and the like. The light pattern can be improved, and the color shift problem shown at different visual angles can be alleviated by virtue of the design of the surface microstructures 341 of the transparent adhesive layer 34.

As shown in FIG. 4B, in an LED display apparatus 30′ in another first embodiment of the present invention, the above LED package structure 10 can be replaced by the LED 10′ with the lens structural layer 20, wherein the lens structural layer 20 is arranged on the black sealant layer 18, and covers the first LED die 12, the second LED die 14, and the third LED die 16. In an embodiment, the material of the lens structural layer 20 can be same with or different from that of the transparent adhesive layer 34. The structure and compositions of the lens structural layer 20 have been revealed in the LED package structure 10′ in the first embodiment shown in FIG. 1B, which are not repeatedly described herein.

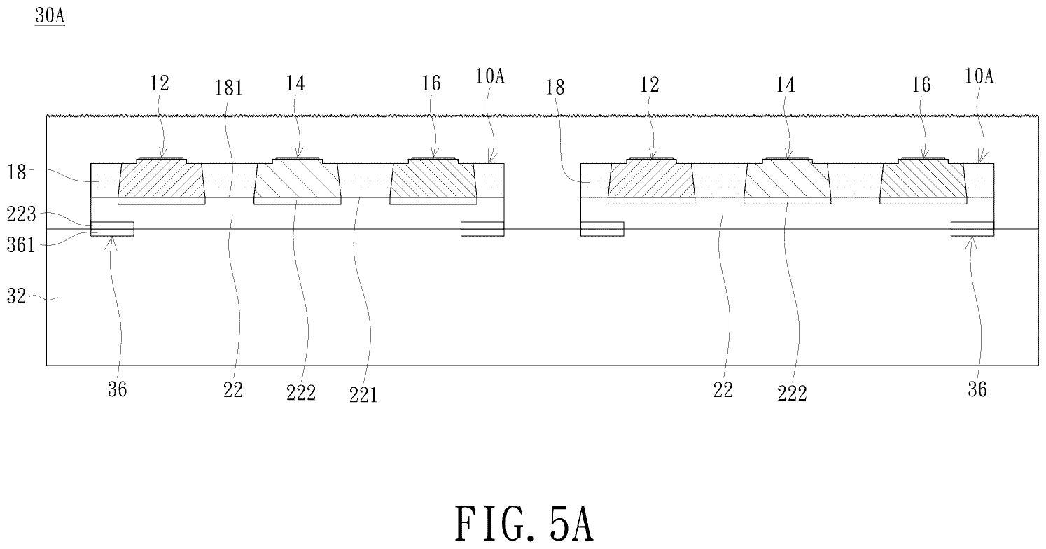

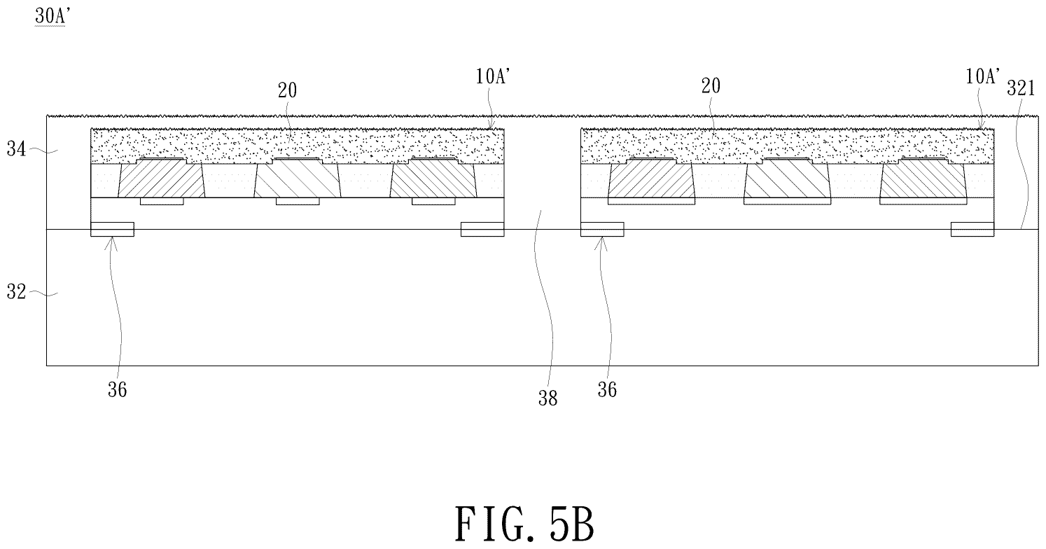

FIG. 5A and FIG. 5B show cross-sectional schematic diagrams of LED display apparatuses according to two second embodiments of the present invention. As shown in FIG. 5A, the difference between the LED display apparatus 30A in the second embodiments and the LED display apparatus 30 in the first embodiments mainly lies in that the LED package structures 10A are different from the LED package structure 10, wherein the LED package structure 10A further includes a package substrate 22, an upper surface 221 of the package substrate 22 is provided with a plurality of welding pads 222, the welding pads 222 are, for example, deposited on the upper surface 221 of the package substrate 22, the joint surface 181 of the black sealant layer 18 contacts with and is connected to the upper surface 221, and the first LED die 12, the second LED die 14, and the third LED die 16 are electrically connected to the welding pads 222, respectively. A conductive circuit structure 223 is exposed to a side of the package substrate 22 away from the black sealant layer 18. When each of the LED package structures 10A, corresponding to one of the circuit endpoint groups 36, is arranged on the circuit substrate 32, the conductive circuit structure 223 exposed on the package substrate 22 contacts with and is electrically connected to the endpoints 361 of each of the circuit endpoint groups 36.

In the LED display apparatus 30A′ in another second embodiment, the above LED package structure 10A can be replaced by the LED package structure 10A′ with the lens structural layer 20. As shown in FIG. 5B, the plurality of LED package structures 10A′ are arranged on the surface 321 of the circuit substrate 32 and are electrically connected to the circuit endpoint groups 36, respectively. The transparent adhesive layer 34 is arranged on the circuit substrate 32, covers the LED package structure 10A′, and fills the gap 38. The structure and compositions of the lens structural layer 20 have been revealed in the LED package structure 10′ in the first embodiment shown in FIG. 1B, which are not repeatedly described herein.

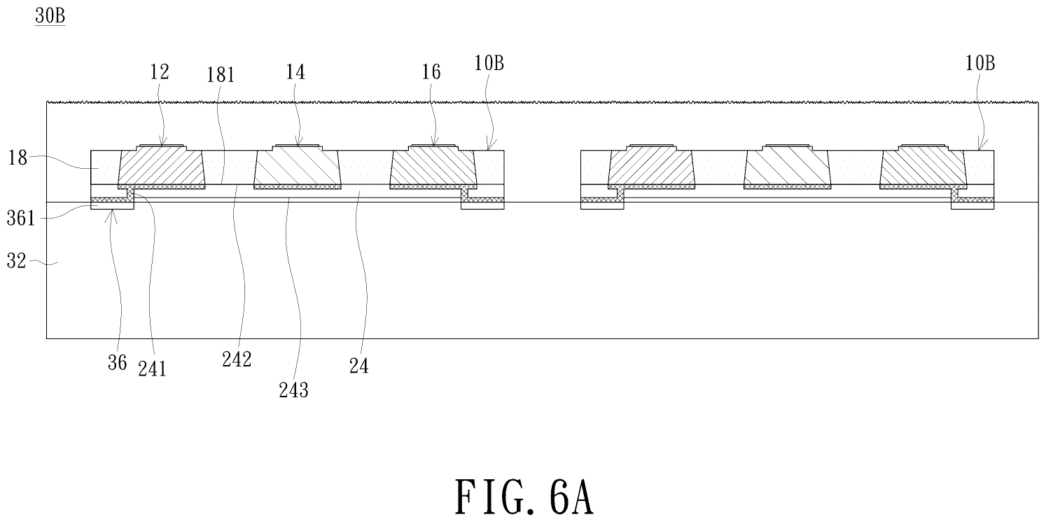

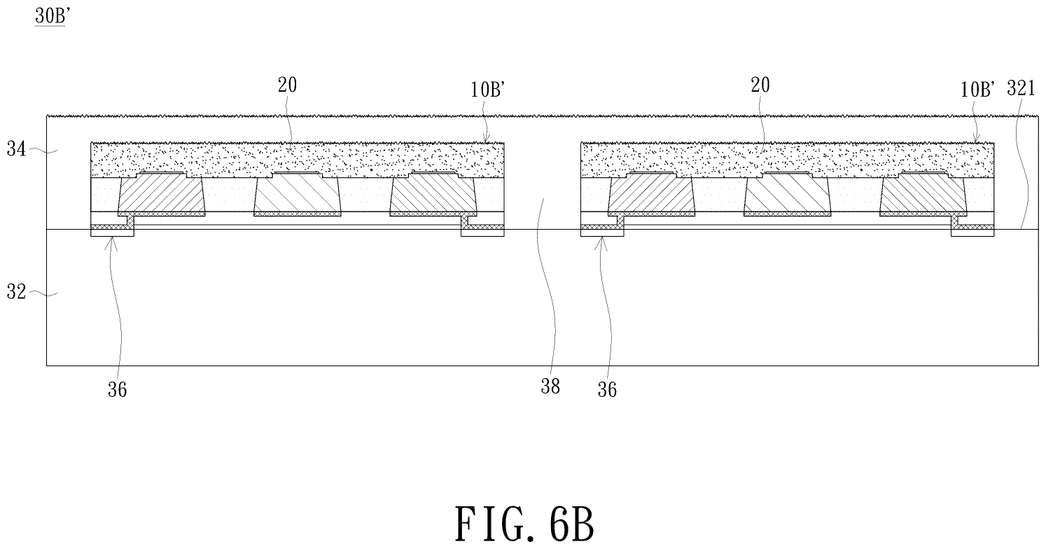

FIG. 6A and FIG. 6B show cross-sectional schematic diagrams of LED display apparatuses according to two third embodiments of the present invention. As shown in FIG. 6A, the difference between the LED display apparatus 30B in the third embodiments and the LED display apparatus 30 in the first embodiments mainly lies in that the LED package structures 10B are different from the LED package structure 10, wherein the LED package structure 10B further includes a redistribution layer 24 including a plurality of fan-out conductive structures 241, a part of the fan-out conductive structures 241 are exposed to the top side 242 and the bottom side 243 of the redistribution layer 24; the joint surface 181 of the black sealant layer 18 contacts with and is connected to the top side 242 of the redistribution layer 24, and the first LED die 12, the second LED die 14, and the third LED die 16 are electrically connected to the part of fan-out conductive structures 241 exposed to the top side 242, respectively. When each of the LED package structures 10B, corresponding to one of the circuit endpoint groups 36, is arranged on the circuit substrate 32, the parts of the fan-out conductive structures 241 exposed to the bottom side 243 of the redistribution layer 24 contact with and are electrically connected to the endpoints 361 of each of the circuit endpoint groups 36.

In the LED display apparatus 30B′ in another second embodiment, the above LED package structure 10B can be replaced by the LED package structure 10B′ with the lens structural layer 20. As shown in FIG. 6B, the plurality of LED package structures 10B′ are arranged on the surface 321 of the circuit substrate 32 and are electrically connected to the circuit endpoint groups 36, respectively. The transparent adhesive layer 34 is arranged on the circuit substrate 32, covers the LED package structure 10B′, and fills the gap 38. The structure and compositions of the lens structural layer 20 have been revealed in the LED package structure 10′ in the first embodiment shown in FIG. 1B, which are not repeatedly described herein.

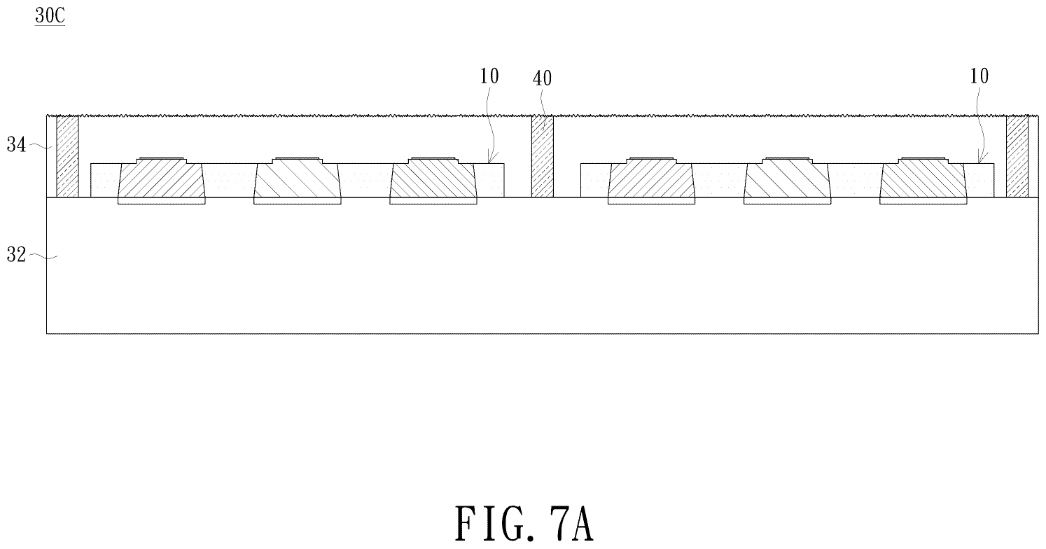

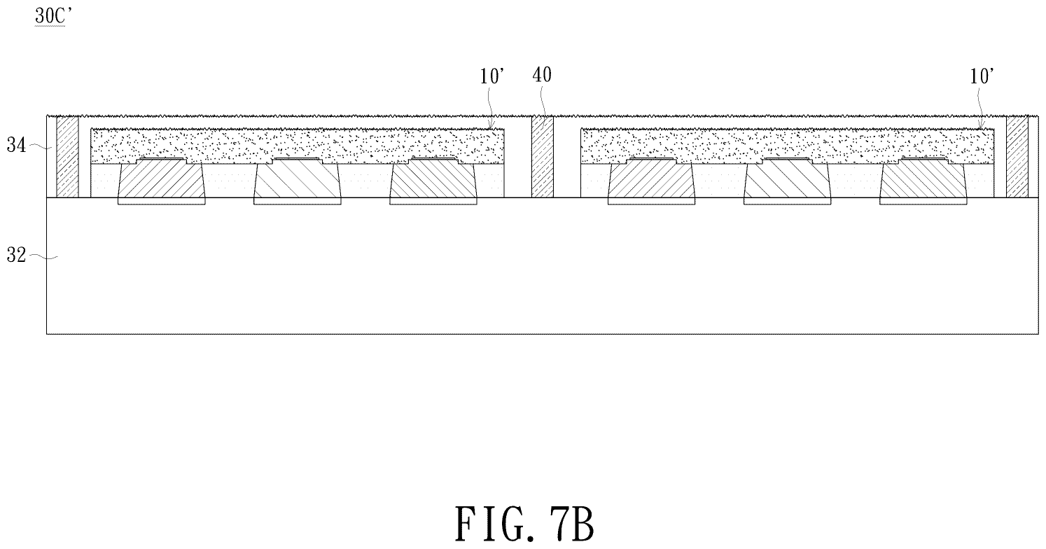

FIG. 7A and FIG. 7B show cross-sectional schematic diagrams of LED display apparatuses according to two fourth embodiments of the present invention. As shown in FIG. 7A/FIG. 7B, the LED display apparatuses 30C/30C′ further include a plurality of spacers 40, arranged on the circuit substrate 32 and located between the LED package structures 10/10′. The transparent adhesive layer 34 further coats the spacers 40. The spacers 40 are made from, for example, a material with the transmittance and refractive index same with or close to those of the transparent adhesive layer 34. Further, a manufacturing method for the spacers 40 may be an injection molding process or an exposed developing process, and the like. Further, although the LED display apparatuses 30C/30C′ shown in FIG. 7A/FIG. 7B are described including the LED package structures 10/10′ in the first embodiments, they are not limited herein. The LED package structures 10/10′ can also be replaced by the LED package structures 10A/10A′ in the second embodiments or the LED package structures 10B/10B′ in the third embodiments.

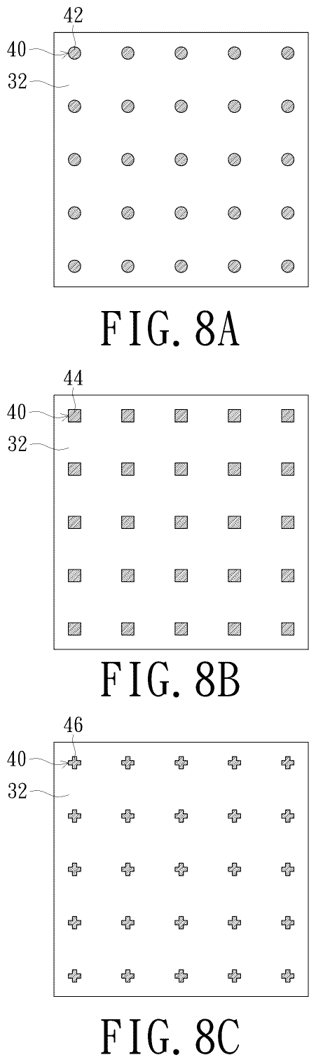

In an embodiment, a shape of each of the spacers 40 is of a single column structure. FIG. 8A, FIG. 8B, and FIG. 8C show top view schematic diagrams of spacers according to an embodiment in different patterns. As shown in the figures, each of the spacers 40 is arranged on the circuit substrate 32 in a single column shape, wherein as shown in FIG. 8A, the spacer 40 includes, for example, a cylindrical structure 42, whose cross-section is, for example, circular; as shown in FIG. 8B, the spacer 40 includes, for example, a square column structure 44, whose cross-section is, for example, square; and as shown in FIG. 8C, the spacer 40 includes, for example, a cross column structure 46, whose cross-section is, for example, cross-shaped.

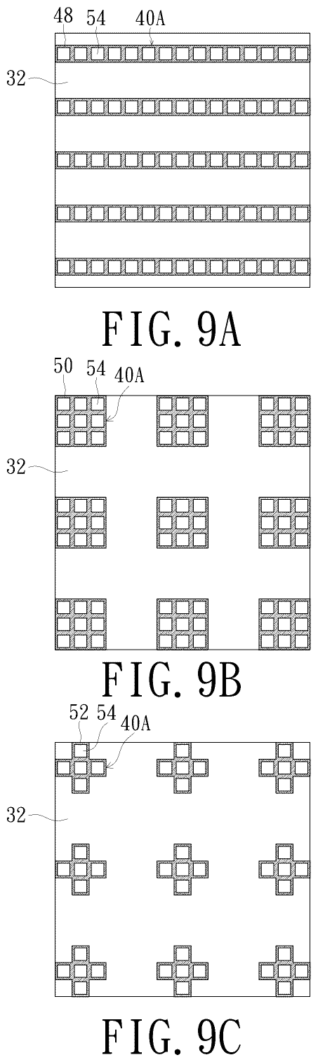

In an embodiment, the shape of each of the spacers 40A is of a perforated array arrangement structure. FIG. 9A, FIG. 9B, and FIG. 9C show top view schematic diagrams of spacers according to another embodiment in different patterns. As shown in FIG. 9A, the spacer 40A includes a body 48 with a section being linear, and a plurality of holes 54 sequentially arranged are formed in the body 48, wherein as shown in FIG. 9A, the five parallel spacers 40A are arranged on the circuit substrate 32, which is not limited herein. As shown in FIG. 9B, the spacer 40A includes a body 50 with a section being rectangular, and a plurality of holes 54 arranged in an array are formed in the body 50; and as shown in FIG. 9C, the spacer 40A includes a body 52 with a section being cross-shaped, and a plurality of holes 54 arranged in an array are formed in the body 52. When the transparent adhesive layer 34 (marked in FIG. 7A/FIG. 7B) coats the spacer 40A, the transparent adhesive layer 34 further fills the holes 54; and further, the shape of each of the holes 54 is not limited to square and can also be other shapes such as roundness.

As the spacers 40/40A of either the single column structure or the perforated array arrangement structure are arranged on the circuit substrate 32 and are located inside the transparent adhesive layer 34, the flatness of a side of the transparent adhesive layer 34 away from the circuit substrate 32 as a light emitting plane can be improved, and a color shift phenomenon as the light emitting plane is not an integrated horizontal plane when the circuit substrate 32 is bent is avoided, so that the display quality of the whole LED display apparatuses 30C/30C′ is improved.

As mentioned above, in the LED package structures in the embodiments of the present invention, every three LED dies in a group are assembled together by utilizing the black sealant layer, and the black sealant layer does not cover the top surfaces of the LED dies. When the LED package structures are jointed to the circuit board, a reflection mechanism of conventional solder paste or a metal conductive adhesive and a circuit layer on a circuit board can be shielded synchronously, so as to prevent affecting contrast of the LED display apparatus, so the LED display apparatus has a better visual taste. In addition, by selecting and arranging the lens structural layer of the LED package structure, the purposes of improving the light pattern of the LED dies and reducing the color shift can further be achieved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An LED package structure, comprising:
a first LED die, provided with a first bottom surface, a first top surface, and a first peripheral wall, wherein the first bottom surface and the first top surface are opposite to each other, and the first peripheral wall is connected to the first bottom surface and the first top surface opposite to each other;
a second LED die, provided with a second bottom surface, a second top surface, and a second peripheral wall, wherein the second bottom surface and the second top surface are opposite to each other, and the second peripheral wall is connected to the second bottom surface and the second top surface opposite to each other;
a third LED die, provided with a third bottom surface, a third top surface, and a third peripheral wall, wherein the third bottom surface and the third top surface are opposite to each other, and the third peripheral wall is connected to the third bottom surface and the third top surface opposite to each other; and
a black sealant layer, coated among the first LED die, the second LED die, and the third LED die and coating the first peripheral wall, the second peripheral wall, and the third peripheral wall, wherein the black sealant layer is provided with a joint surface, the joint surface is coplanar with the first bottom surface, the second bottom surface, and the third bottom surface, and the black sealant layer does not cover the first top surface, the second top surface, and the third top surface.

2. The LED package structure according to claim 1, wherein the first LED die, the second LED die, and the third LED die are respectively a blue LED die, a green LED die, and a red LED die.

3. The LED package structure according to claim 1, wherein the LED package structure further comprises a lens structural layer, arranged on the black sealant layer and covering the first LED die, the second LED die, and the third LED die.

4. The LED package structure according to claim 3, wherein the lens structural layer comprises a resin material layer and a plurality of white diffusive particles, and the white diffusive particles are distributed in the resin material layer.

5. The LED package structure according to claim 3, wherein the lens structural layer comprises a resin material layer, a plurality of white acrylic spheres, and a black film layer, the white acrylic spheres are distributed in the resin material layer, and the black film layer is arranged on a side of the resin material layer away from the black sealant layer.

6. The LED package structure according to claim 3, wherein the lens structural layer comprises a resin material layer and a plurality of black powder particles, and the black powder particles are distributed in the resin material layer.

7. The LED package structure according to claim 3, wherein a plurality of microstructures are formed on a side of the lens structural layer away from the black sealant layer.

8. The LED package structure according to claim 1, wherein the LED package structure further comprises a package substrate, an upper surface of the package substrate is provided with a plurality of welding pads, the joint surface of the black sealant layer is connected to the upper surface, and the first LED die, the second LED die, and the third LED die are electrically connected to the welding pads, respectively.

9. The LED package structure according to claim 8, wherein the LED package structure further comprises a lens structural layer, arranged on the black sealant layer and covering the first LED die, the second LED die, and the third LED die.

10. The LED package structure according to claim 1, wherein the LED package structure further comprises a redistribution layer comprising a plurality of fan-out conductive structures, the joint surface of the black sealant layer is connected to the redistribution layer, and the first LED die, the second LED die, and the third LED die are electrically connected to the fan-out conductive structures, respectively.

11. The LED package structure according to claim 10, wherein the LED package structure further comprises a lens structural layer, arranged on the black sealant layer and covering the first LED die, the second LED die, and the third LED die.

12. An LED display apparatus, comprising:
a circuit board, provided with a plurality of circuit endpoint groups, wherein each of the circuit endpoint groups comprises at least three endpoints;
a plurality of LED package structures, arranged on the circuit board and electrically connected to the circuit endpoint groups, receptively, each of the LED package structures comprising a first LED die, a second LED die, a third LED die, and a black sealant layer, wherein
the first LED die, the second LED die, and the third LED die respectively contact and are electrically connected to the at least three endpoints of each of the circuit endpoint groups;
the black sealant layer is coated among the first LED die, the second LED die, and the third LED die and coats a first peripheral wall of the first LED die, a second peripheral wall of the second LED die, and a third peripheral wall of the third LED die, and the black sealant layer does not cover the first LED die, the second LED die, and the third LED die; and
the black sealant layer of each of the LED package structures is not connected to the black sealant layer of another adjacent LED package structure, and there is a gap between the black sealant layers; and
a transparent adhesive layer, arranged on the circuit board, covering the LED package structures, and filling the gap.

13. The LED display apparatus according to claim 12, wherein a plurality of surface microstructures are formed on a side of the transparent adhesive layer away from the circuit board.

14. The LED display apparatus according to claim 12, wherein a plurality of ultraviolet absorption particles are distributed in the transparent adhesive layer.

15. The LED display apparatus according to claim 12, wherein the LED package structures are adhered to the circuit board via a metal conductive adhesive.

16. The LED display apparatus according to claim 12, wherein each of the LED package structures further comprises a lens structural layer, arranged on the black sealant layer and covering the first LED die, the second LED die, and the third LED die.

17. The LED display apparatus according to claim 12, wherein each of the LED package structures further comprises a package substrate, located between the circuit board and the black sealant layer, an upper surface of the package substrate is provided with a plurality of welding pads, and the first LED die, the second LED die, and the third LED die are electrically connected to the welding pads, respectively.

18. The LED display apparatus according to claim 17, wherein each of the LED package structures further comprises a lens structural layer, arranged on the black sealant layer and covering the first LED die, the second LED die, and the third LED die.

19. The LED display apparatus according to claim 12, wherein each of the LED package structures further comprises a redistribution layer, located between the circuit board and the black sealant layer and comprising a plurality of fan-out conductive structures, and the first LED die, the second LED die, and the third LED die are electrically connected to the fan-out conductive structures, respectively.

20. The LED display apparatus according to claim 19, wherein each of the LED package structures further comprises a lens structural layer, arranged on the black sealant layer and covering the first LED die, the second LED die, and the third LED die.

21. The LED display apparatus according to claim 12, wherein the LED display apparatus further comprises a plurality of spacers, arranged on the circuit board and located among the LED package structures, and the transparent adhesive layer further coats the spacers.

22. The LED display apparatus according to claim 21, wherein a shape of each of the spacers is of a single column structure.

23. The LED display apparatus according to claim 21, wherein the shape of each of the spacers is of a perforated array arrangement structure.

24. The LED display apparatus according to claim 21, wherein the transmittance and refractive index of the spacers correspond to the transmittance and refractive index of the transparent adhesive layer.
